(19) United States
(12) Patent Application Publication
(10) Pub. No.: US 2016/0126251 A1
(43) Pub. Date: May 5, 2016

(54) SEMICONDUCTOR MEMORY DEVICE AND METHOD FOR MANUFACTURING SAME

(71) Applicant: Kabushiki Kaisha Toshiba, Minato-ku (JP)

(72) Inventors: Masanari FUJITA, Yokkaichi (JP); Yoshiaki FUKUZUMI, Yokkaichi (JP)

(73) Assignee: Kabushiki Kaisha Toshiba, Minato-ku (JP)

(21) Appl. No.: 14/601,384

(22) Filed: Jan. 21, 2015

Related U.S. Application Data
(60) Provisional application No. 62/072,876, filed on Oct. 30, 2014.

(51) Int. Cl. H01L 27/115; H01L 29/49

(52) U.S. Cl. CPC H01L 27/11582; H01L 29/495

(57) ABSTRACT

According to one embodiment, a semiconductor memory device includes a substrate that includes a first region and a second region; a stacked body that is disposed on the first region of the substrate and includes a plurality of first metal layers and a plurality of voids each of which is disposed between the plurality of first metal layers; a columnar portion that penetrates the stacked body, extends in a direction of stacking in the stacking body; a transistor that is disposed on the second region; and the interconnect portion that is disposed on the transistor and includes the plurality of first metal layers and a plurality of second metal layers each of which is disposed between the plurality of first metal layers. The transistor is electrically connected to the channel body or the first metal layer of the stacked body through a interconnect portion.

This application is based upon and claims the benefit of priority from U.S. Provisional Patent Application 62/072,876 field on Oct. 30, 2014; the entire contents of which are incorporated herein by reference.

### FIELD

Embodiments described herein relate generally to a semiconductor memory device and a method for manufacturing same.

### BACKGROUND

A three-dimensionally structured memory device is proposed. In the memory device, a memory hole is formed in a stacked body in which an electrode layer that functions as a control gate in a memory cell is plurally stacked with an insulating film interposed between the electrode layers, and a silicon body that serves as a channel is disposed on a side wall of the memory hole with a charge storage film interposed between the side wall and the silicon body.

The speed of operation of the memory device is required to be increased by using simple processes.

### BRIEF DESCRIPTION OF THE DRAWINGS

FIG.1 is a schematic perspective view of a memory cell array of an embodiment;

FIG.2 is a schematic cross-sectional view of the memory cell array of the embodiment;

FIG. 3 is a schematic cross-sectional view of the memory cell array and a peripheral circuit portion of the embodiment;

FIG. 4 is an enlarged schematic cross-sectional view of a part of the columnar section of the embodiment;

FIG.5 to FIG.12 are schematic views showing a method for manufacturing the semiconductor memory device of the embodiment; and

FIG. 13 is a schematic view of another example of the memory cell array of the embodiment.

### DETAILED DESCRIPTION

According to one embodiment, a semiconductor memory device includes a substrate that includes a first region and a second region; a stacked body that is disposed on the first region of the substrate and includes a plurality of first metal layers and a plurality of voids each of which is disposed between the plurality of first metal layers; a columnar portion that penetrates the stacked body, extends in a direction of stacking in the stacking body; a transistor that is disposed on the second region; and the interconnect portion that is disposed on the transistor and includes the plurality of first metal layers and a plurality of second metal layers each of which is disposed between the plurality of first metal layers. The columnar portion includes a channel body which extends in the direction of stacking, and a charge storage film which is disposed between the channel body and each of the first metal layers. The transistor is electrically connected to the channel body or the first metal layer of the stacked body through a interconnect portion.

Hereinafter, an embodiment will be described with reference to the accompanying drawings. The same constituent in each drawing is given the same reference sign.

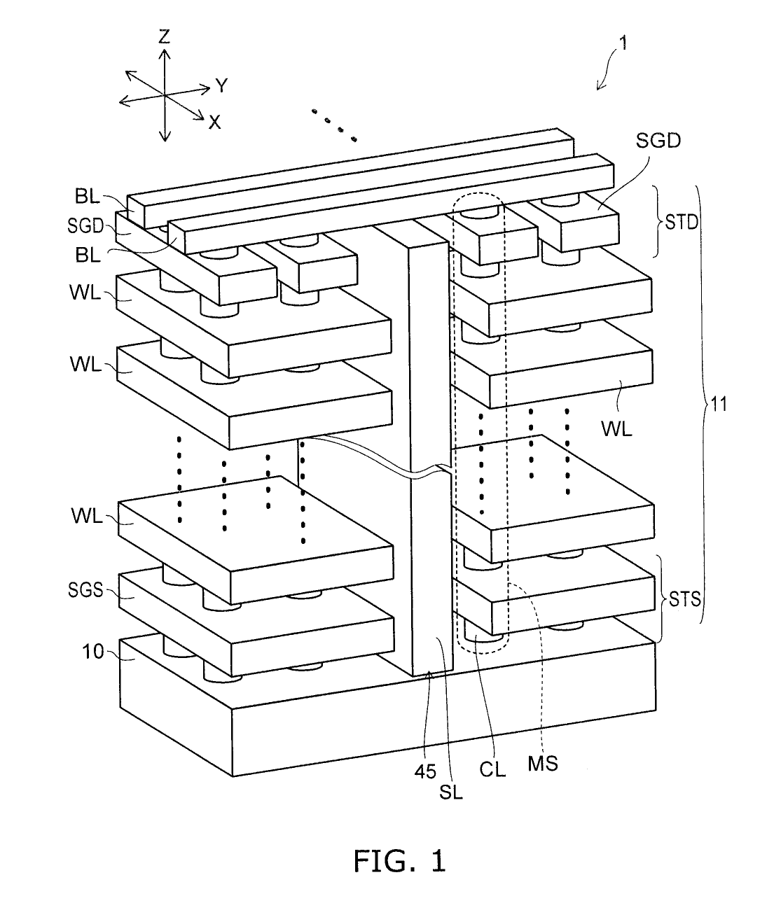

FIG. 1 is a schematic perspective view of a memory cell array of the embodiment. Illustrations of an insulating layer and the like are omitted for easy understanding in FIG. 1.

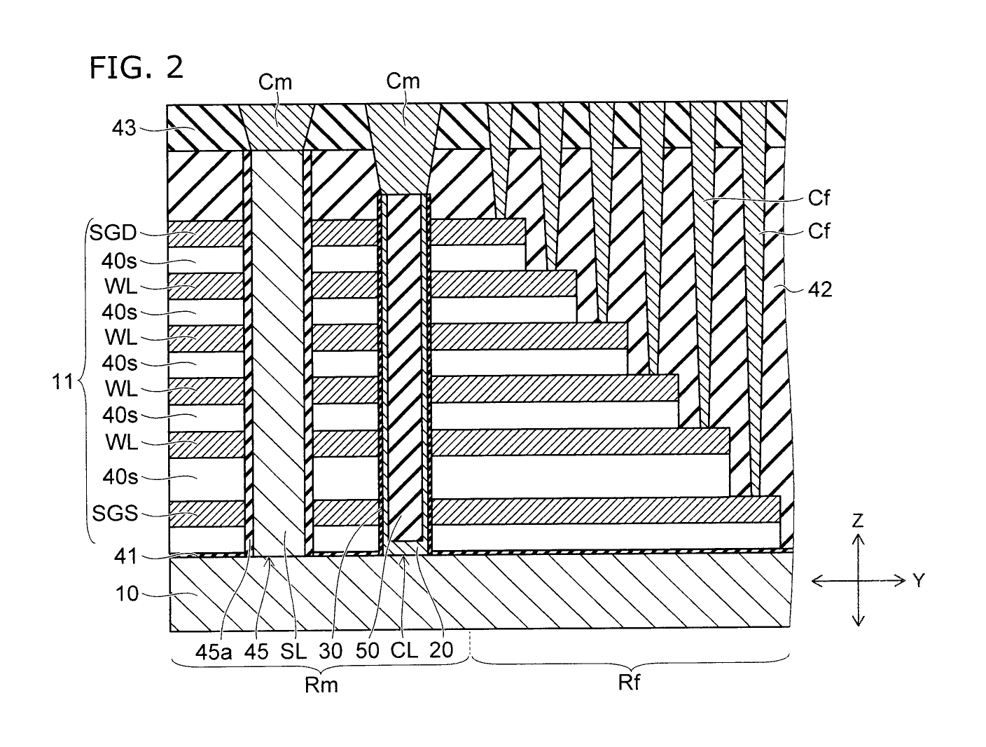

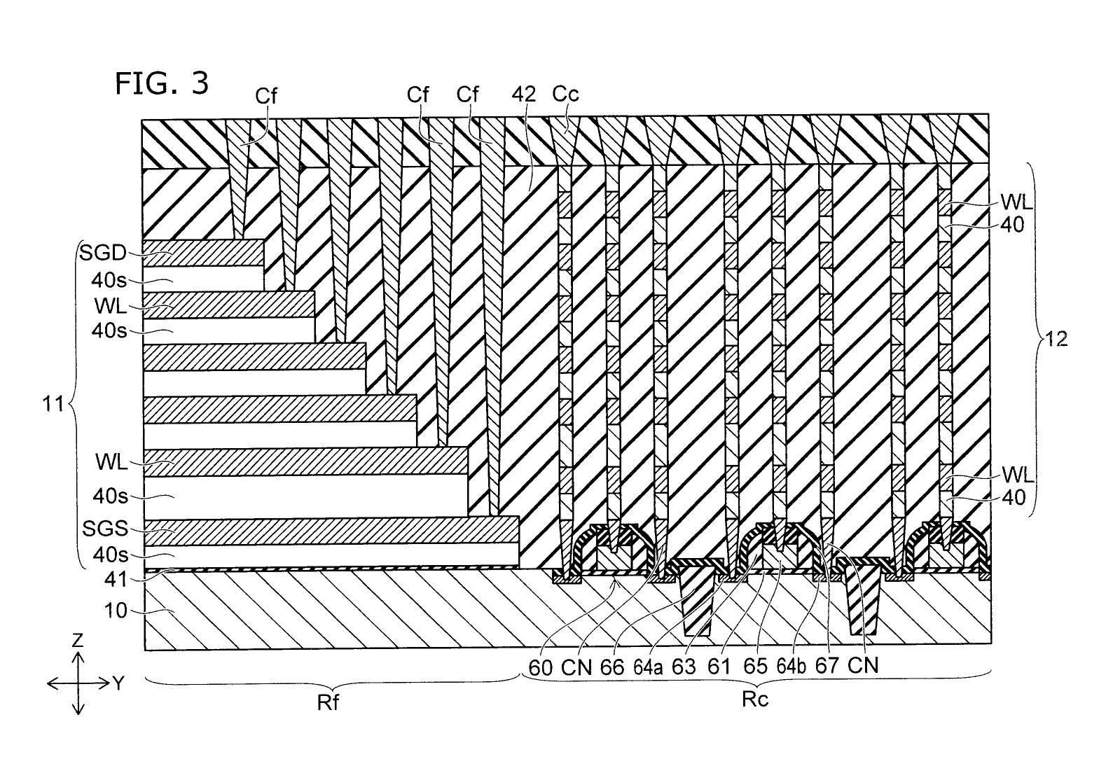

FIG. 2 is a schematic cross-sectional view of the memory cell array of the embodiment. FIG. 3 is a schematic cross-sectional view of a peripheral circuit portion of the memory cell array of the embodiment.

In FIG. 1, two directions that are parallel to the major surface of a substrate 10 and are orthogonal to each other are set as an X-direction and a Y-direction, and a direction that is orthogonal to both of the X-direction and the Y-direction is set as a Z-direction (direction of stacking).

A memory cell array 1 includes a plurality of memory strings MS as illustrated in FIG. 1.

A source-side selector gate SGS is disposed on the substrate 10 with an insulating layer 41 and a void 40s interposed therebetween. The void 40s is disposed on the source-side selector gate SGS. A stacked body 11 is disposed on the void 40s. In the stacked body 11, a plurality of electrode layers WL (first metal layer) is stacked with the void 40s interposed therebetween. The number of electrode layers WL is illustrated as an example in the drawings and is arbitrary. The plurality of electrode layers is, for example, separately stacked each other.

The void 40s is disposed on the uppermost electrode layer WL, and a drain-side selector gate SGD is disposed on the void 40s. The stacked body 11 includes the source-side selector gate SGS, the plurality of electrode layers WL thereon, and the drain-side selector gate SGD.

The source-side selector gate SGS, the drain-side selector gate SGD, and the electrode layer WL include metal. For example, tungsten is used. The drain-side selector gate SGD and the source-side selector gate SGS, for example, may be disposed plurally.

A columnar portion CL is disposed in the stacked body 11 extending in the Z-direction. The columnar portion CL penetrates the stacked body 11. The columnar portion CL, for example, is formed as a cylinder or an elliptic cylinder. The columnar portion CL is electrically connected to the substrate 10.

A groove 45 is disposed in the stacked body 11 penetrating the stacked body 11. A source layer SL is disposed in the groove 45, and the side surface of the source layer SL is covered by an insulating film 45a. Conductive material is used as the source layer SL.

The lower end of the source layer SL is electrically connected to a channel body 20 (semiconductor body) of the columnar portion CL through the substrate 10. The upper end of the source layer SL is electrically connected to a transistor 60 in a peripheral circuit region Rc through unillustrated upper layer wiring.

The source layer SL, for example, may be disposed between the substrate 10 and the stacked body 11. In this case, an unillustrated contact layer is disposed in the groove 45, and the source layer SL is electrically connected to the transistor 60 in the peripheral circuit region Rc through the contact layer and upper layer wiring.

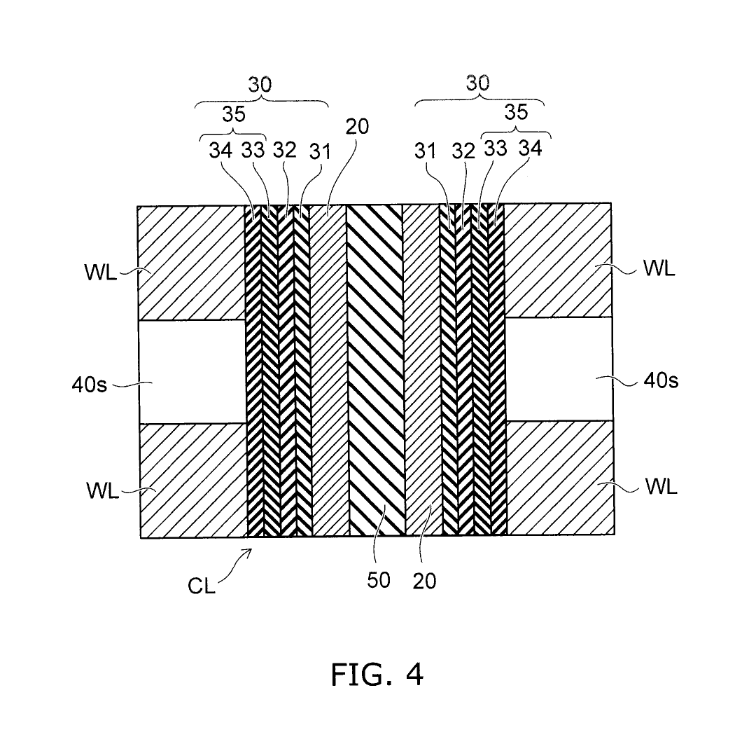

FIG. 4 is a schematic cross-sectional view of an enlarged part of the columnar portion CL of the embodiment.

The columnar portion CL is formed in a memory hole that is formed in the stacked body 11 which includes the plurality of electrode layers WL and a plurality of voids 40s. The channel body 20 is disposed in the memory hole as a semiconductor channel. The channel body 20, for example, is a silicon film that includes silicon as a main component.

The channel body 20 is disposed as a tube that extends in the direction of stacking in the stacked body 11. The upper end of the channel body 20 is connected to a bit line BL (wiring) illustrated in FIG. 1, and the lower end of the channel body 20 is connected to the substrate 10. Each bit line BL extends in the Y-direction.

A memory film 30 is disposed between the electrode layer WL and the channel body 20. The memory film 30 includes a block insulating film 35, a charge storage film 32, and a tunnel insulating film 31.

The block insulating film 35, the charge storage film 32, and the tunnel insulating film 31 are disposed between the electrode layer WL and the channel body 20 in this order from the electrode layer WL side. The block insulating film 35 is in contact with the electrode layer WL, and the tunnel insulating film 31 is in contact with the channel body 20. The charge storage film 32 is disposed between the block insulating film 35 and the tunnel insulating film 31.

The electrode layer WL surrounds the channel body 20 with the memory film 30 interposed therebetween. A core insulating film 50 is disposed inside the channel body 20.

The channel body 20 functions as a channel in a memory cell, and the electrode layer WL functions as a control gate of the memory cell. The charge storage film 32 functions as a data memory layer that stores charges implanted from the channel body 20. That is, the memory cell structured in a manner in which the control gate surrounds the channel is formed at the intersection part of the channel body 20 and each electrode layer WL.

A semiconductor memory device of the embodiment can freely delete or write data electrically and can hold the contents of the memory even when power is turned off.

The memory cell, for example, is a charge trap type. The charge storage film 32, for example, is a silicon nitride film and plurally includes trap sites that capture charges.

The tunnel insulating film 31 serves as a potential barrier when charges are implanted to the charge storage film 32 from the channel body 20 or when charges stored in the charge storage film 32 are diffused into the channel body 20. The tunnel insulating film 31, for example, is a silicon oxide film.

Alternatively, a stacked film (ONO film) that is structured in a manner in which a silicon nitride film is interposed between a pair of silicon oxide films may be used as the tunnel insulating film 31. When the ONO film is used as the tunnel insulating film 31, a deletion operation is performed with a low electric field compared with a case of using a single silicon oxide film.

The block insulating film 35 prevents charges stored in the charge storage film 32 from being diffused into the electrode layer WL. The block insulating film 35 includes a cap film 34 that is disposed in contact with the electrode layer WL and a block film 33 that is disposed between the cap film 34 and the charge storage film 32.

The block film 33, for example, is a silicon oxide film. The cap film 34 has a higher dielectric constant than silicon oxide and, for example, is a silicon nitride film. Disposing such cap film 34 in contact with the electrode layer WL can suppress back tunneling of electrons that are implanted from the electrode layer WL during deletion. That is, using a stacked film of a silicon oxide film and a silicon nitride film as the block insulating film 35 can increase the ability to block charges.

A drain-side selector transistor STD is disposed in the upper end portion of the columnar portion CL, and a source-side selector transistor STS is disposed in the lower end portion of the columnar portion CL in a memory string MS as illustrated in FIG. 1.

The memory cell, the drain-side selector transistor STD, and the source-side selector transistor STS are vertical transistors in which currents flow in the direction of stacking (Z-direction) in the stacked body 11.

The drain-side selector gate SGD functions as the gate electrode (control gate) of the drain-side selector transistor STD. An insulating film is disposed between the drain-side selector gate SGD and the channel body 20 functioning as a gate insulating film of the drain-side selector transistor STD.

The source-side selector gate SGS functions as the gate electrode (control gate) of the source-side selector transistor STS. An insulating film is disposed between the source-side selector gate SGS and the channel body 20 functioning as a gate insulating film of the source-side selector transistor STS.

A plurality of memory cells is disposed between the drain-side selector transistor STD and the source-side selector transistor STS with each electrode layer WL as the control gate.

The plurality of memory cells, the drain-side selector transistor STD, and the source-side selector transistor STS are connected in series through the channel body 20 and constitute one memory string MS. The plurality of memory cells is disposed three-dimensionally in the X-direction, the Y-direction, and the Z-direction by arranging the memory strings MS plurally in the X-direction and the Y-direction.

The substrate 10 includes a memory region Rm (first region), a flight region Rf, and the peripheral circuit region Rc (second region) as illustrated in FIG. 2 and FIG. 3.

The stacked body 11 that is disposed on the memory region Rm extends on the flight region Rf. Each electrode layer WL of the stacked body 11 is disposed as a flight. A lower step layer of the stacked body 11 is formed further from the memory region Rm on the flight region Rf. The flight-shaped electrode layers WL are covered by an insulating layer 42.

A contact portion Cf is disposed on the upper surface of each electrode layer WL, the source-side selector gate SGS, and the drain-side selector gate SGD of the stacked body 11 that is exposed to the insulating layer 42. The contact portion Cf penetrates the insulating layer 42 to reach each electrode layer WL, the source-side selector gate SGS, and the drain-side selector gate SGD. Accordingly, each electrode layer WL, the source-side selector gate SGS, and the drain-side selector gate SGD are electrically connected to the transistor 60 on the peripheral circuit region Rc through unillustrated upper layer wiring.

The flight region Rf is disposed between the memory region Rm and the peripheral circuit region Rc. The transistor 60 is disposed in the peripheral circuit region Rc. The transistor 60 includes a gate insulating film 61, a spacer (side wall insulating film) 63, diffusion layers 64a and 64b, a gate electrode 65, and a cover film (insulating film) 67. A device isolation portion 66 is disposed between each transistor 60.

The gate insulating film 61 is disposed on the substrate 10. The gate electrode 65 is disposed on the gate insulating film 61. The spacer 63 is disposed on the side surface of the gate electrode 65. The diffusion layers 64a and 64b are disposed in a region that is adjacent to the substrate 10 under the spacer 63. The diffusion layers 64a and 64b may be provided in a manner in which one is on the drain side, and the other is on the source side.

The transistor 60 is covered by a cover film 67. A interconnect portion 12 is disposed on the cover film 67. The plurality of electrode layers (first metal layers) WL and a plurality of metal layers (second metal layers) 40 are alternately stacked on each other one by one in the interconnect portion 12. The resistance value of the electrode layer WL, for example, is smaller than the resistance value of the metal layer 40.

The interconnect portion 12 in the peripheral circuit region Rc is covered by the insulating layer 42 and is separated from the stacked body 11 in the memory region Rm. Each interconnect portion 12 extends in the Z-direction and is separately disposed in the X-direction and the Y-direction.

As will be described below, the interconnect portion 12 is formed separately from the stacked body 11 in the memory region Rm after a metal stacked film that includes the electrode layer (first metal layer) WL and the metal layer (second metal layer) 40 is formed on the entire surface of the substrate 10. For this reason, the number of electrode layers WL in the stacked body 11 is smaller than or equal to the number of electrode layers WL in the interconnect portion 12. In addition, the thickness of the electrode layer WL in the stacked body 11 is the same as the thickness of the electrode layer WL in the interconnect portion 12.

The same material as in the stacked body 11 such as tungsten is used as the electrode layer WL in the interconnect portion 12. For example, at least one of titanium and molybdenum is used as the metal layer 40. Accordingly, the interconnect portion 12 as metal wiring (contact) can allow currents to flow therein. The interconnect portion 12, for example, is connected to a contact portion CN that extends from the transistor 60. Accordingly, the transistor 60 is electrically connected to the interconnect portion 12 through the contact portion CN.

The gate electrode 65 and each of the diffusion layers 64a and 64b of the transistor 60 are electrically connected to the interconnect portion 12 through the contact portion CN. The gate electrode 65 and each of the diffusion layers 64a and 64b, for example, are electrically connected to the electrode layer WL, the source-side selector gate SGS, and the drain-side selector gate SGD of the stacked body 11 through the interconnect portion 12. That is, the transistor 60 is electrically connected to at least one of the stacked body 11 and the columnar portion CL through the interconnect portion 12.

According to the embodiment, the interconnect portion 12 in the peripheral circuit region Rc can be used as a metal wiring (contact) to connect the stacked body 11 in the memory region Rm and the transistor 60 in the peripheral circuit region Rc electrically. As will be described below, the interconnect portion 12 is formed by separating the stacked body 11 in which the memory cell array 1 is formed. For this reason, wiring does not have to be newly formed since the interconnect portion 12 in the peripheral circuit region Rc is used as wiring. Thus, a manufacturing process can be shortened.

Furthermore, the interconnect portion 12 includes the electrode layer WL and the metal layer 40 in which metal is used. Accordingly, the interconnect portion 12 can be used as metal wiring with low electrical resistance. This can increase the speed of operation of a memory.

In addition to the above description, the electrode layer WL of metal is used in the stacked body 11 in the memory region Rm like in the interconnect portion 12 in the peripheral circuit region Rc, and the void 40s is disposed between the electrode layers WL. Accordingly, capacitance can be lowered between the electrode layers WL. Furthermore, using metal in the electrode layer WL can reduce the resistance.

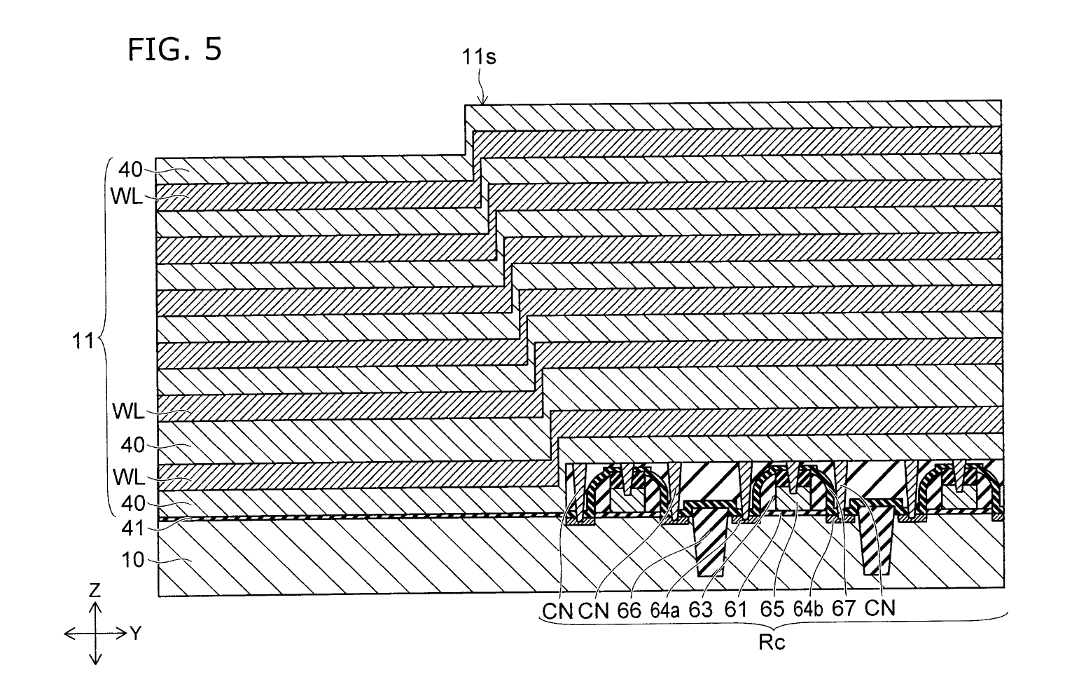

Next, a method for manufacturing the semiconductor memory device of the embodiment will be described with reference to FIG. 5 to FIG. 12.

The transistor 60 is formed on the peripheral circuit region Rc of the substrate 10, and the insulating layer 41 is formed on the region except the peripheral circuit region Rc of the substrate 10 as illustrated in FIG. 5. The transistor 60, for example, is structured as a metal-oxide-semiconductor field-effect transistor (MOSFET). The stacked body 11 in which the electrode layer (first metal layer) WL and the metal layer (second metal layer) 40 are alternately stacked on each other is formed on the transistor 60 and the insulating layer 41.

For example, tungsten is used as the electrode layer WL of the stacked body 11, and at least one of titanium and molybdenum is used as the metal layer 40. A step portion 11s is formed in the stacked body 11 between the flight region Rf and the peripheral circuit region Rc.

First, the device isolation portion 66 that isolates a plurality of the transistors 60 is formed as a method for forming the transistor 60 on the peripheral circuit region Rc of the substrate 10. The device isolation portion 66 is formed in the substrate 10. The gate insulating film 61 is formed on the substrate 10. The gate electrode 65 is formed on the gate insulating film 61.

The spacer 63 is formed on the side surface of the gate electrode 65. The diffusion layers 64a and 64b are formed in the substrate 10 beside the spacer 63 by implanting impurities into the substrate 10. The cover film 67 is formed over the gate electrode 65, around the spacer 63, and on the diffusion layers 64a and 64b. Accordingly, the transistor 60 is formed.

Thereafter, the insulating layer 42 is formed around the transistor 60, and the contact portion CN is formed reaching the gate electrode 65 and the diffusion layers 64a and 64b from the upper portion of the insulating layer 42. Thereafter, the above-described stacked body 11 is formed on the transistor 60.

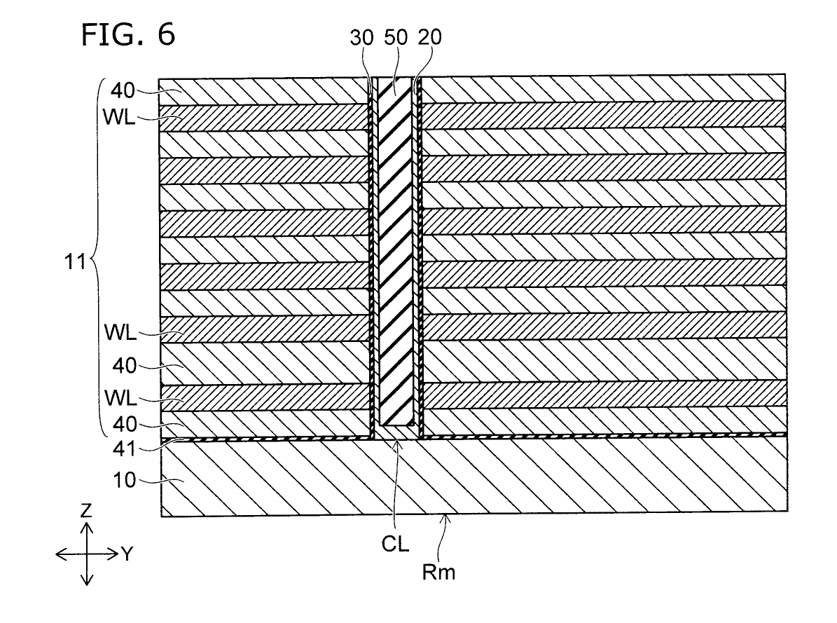

The columnar portion CL is formed in the stacked body 11 on the memory region Rm as illustrated in FIG. 6. First, a hole is formed penetrating the stacked body 11 to reach the substrate 10 as a method for forming the columnar portion CL. Reactive ion etching (RIE) with an unillustrated mask, for example, is used as a method for forming the hole. At this time, the stacked body 11 can be processed through a single process with the same gas since metal is stacked therein.

Thereafter, the memory film 30 illustrated in FIG. 4 is formed on the inner wall (the side wall and the bottom portion) of the hole. Then, the hole is formed penetrating the memory film 30 from the bottom portion of the hole to reach the substrate 10.

Next, the channel body 20 is formed inside the memory film 30, and the core insulating film 50 is formed inside the channel body 20. The lower end portion of the channel body 20 is in contact with the substrate 10. Thereafter, each film formed on the upper surface of the stacked body 11 is removed. Accordingly, the columnar portion CL is formed.

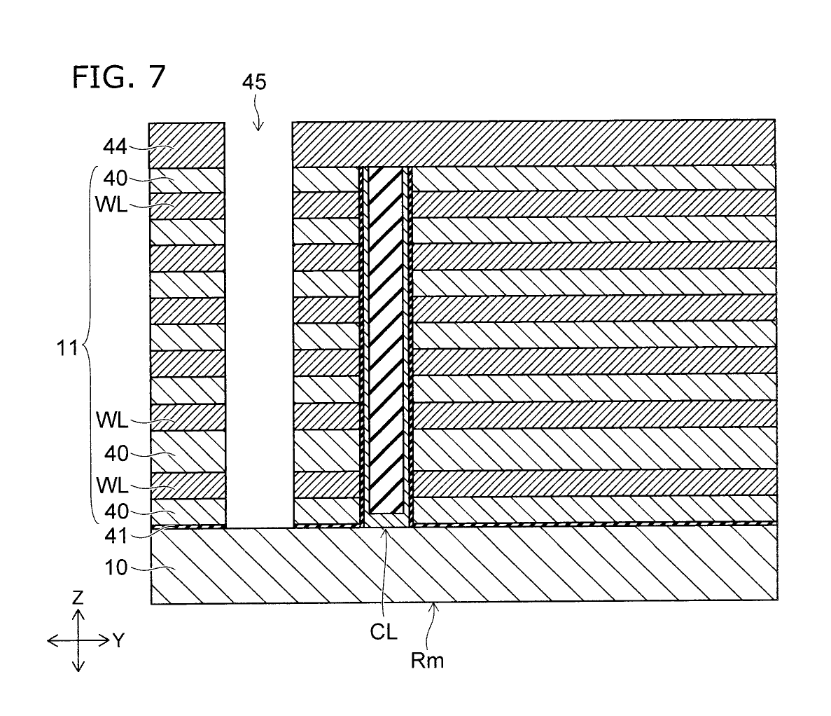

A conductive film 44 is formed in the uppermost portion of the stacked body 11 as illustrated in FIG. 7. The conductive film 44 may be formed when forming a contact portion Cm that will be described below. The groove 45 is formed after the conductive film 44 is formed, penetrating the conductive film 44 and the stacked body 11 to reach the substrate 10. The groove 45, for example, is formed through RIE with an unillustrated mask.

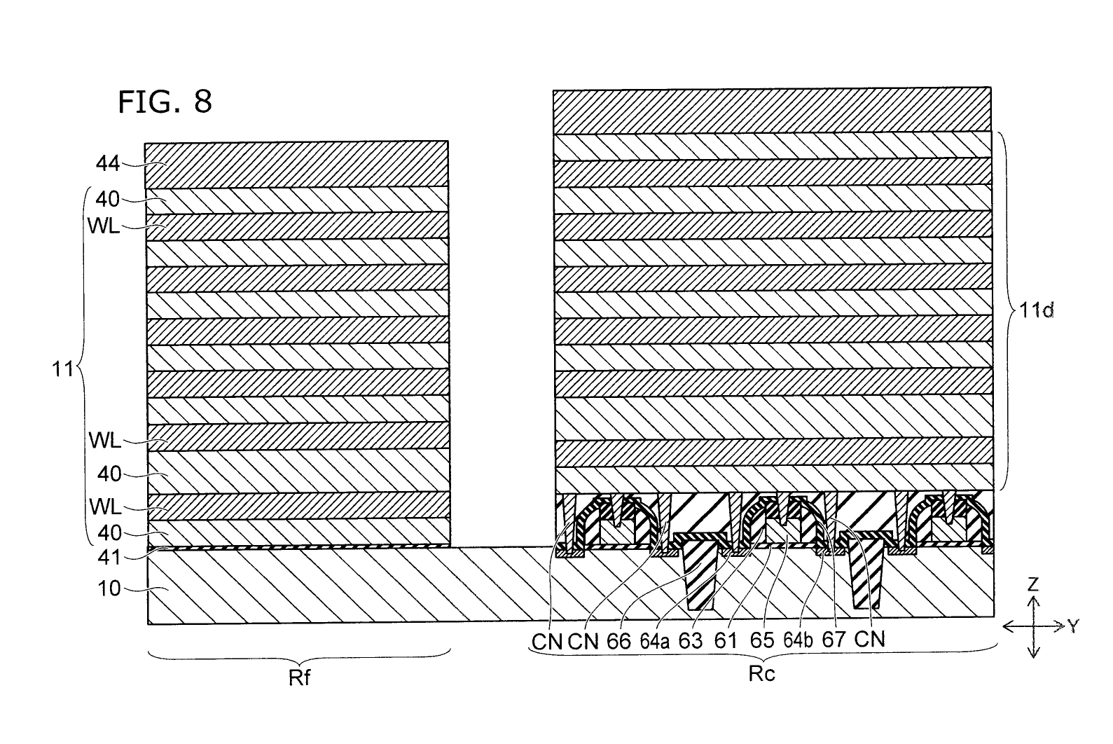

The step portion 11s that is formed between the flight region Rf and the peripheral circuit region Rc is removed as illustrated in FIG. 8. Accordingly, the stacked body 11 is separated into the stacked body 11 (second stacked portion) from the memory region Rm to the flight region Rf and a stacked portion 11d (first stacked portion) on the peripheral circuit region Rc. RIE, for example, is used as a method for removing the step portion 11s.

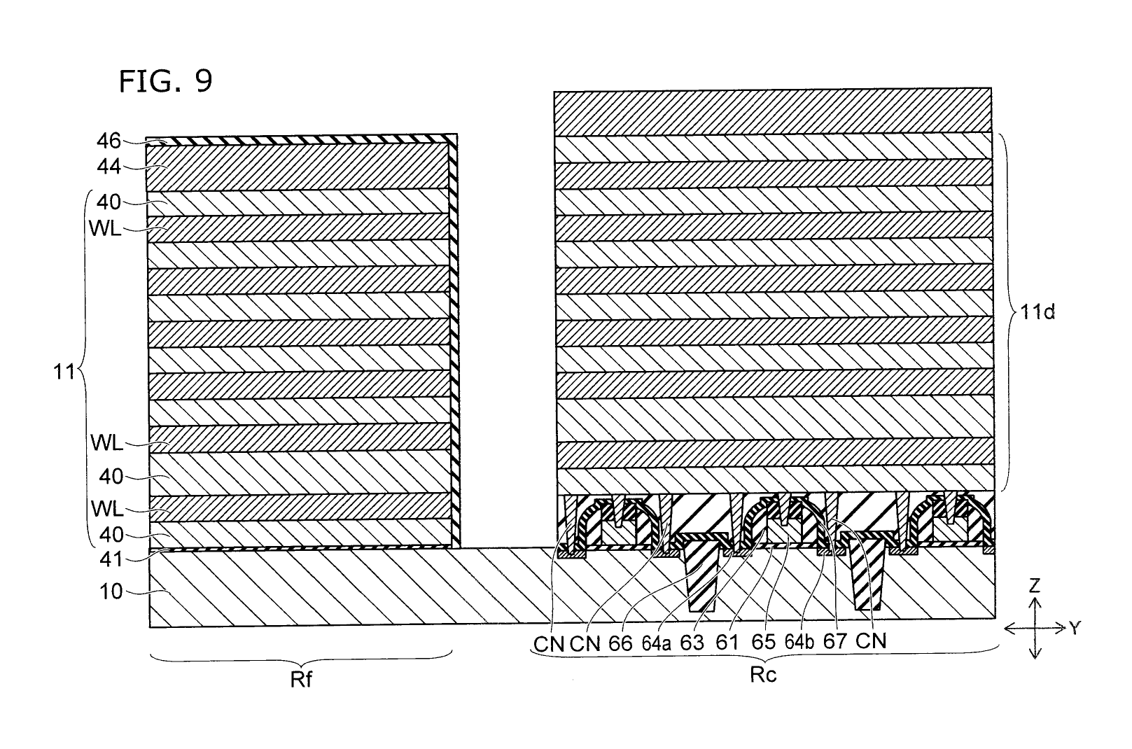

An insulating layer 46 is formed on the wall surface (the upper surface and the side surface) of the stacked body 11 on the flight region Rf and the memory region Rm as illustrated in FIG. 9. The insulating layer 46 is not formed on the wall surface of the stacked portion 11d on the peripheral circuit region Rc. Accordingly, only the stacked portion 11d can be processed.

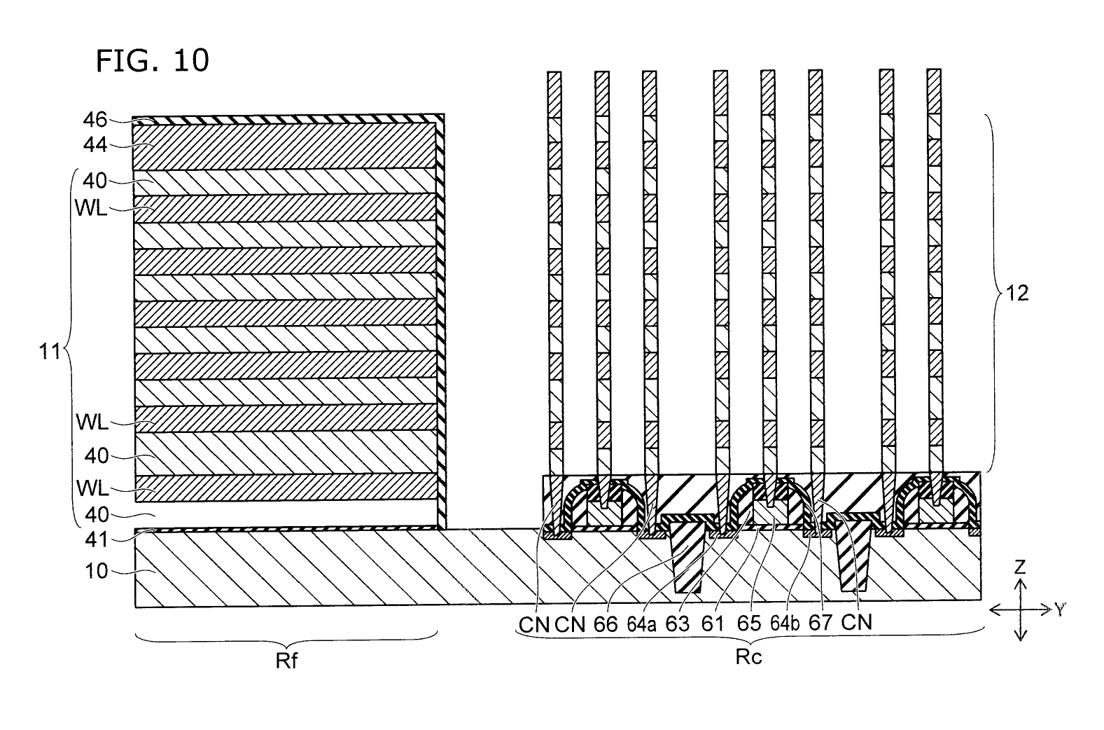

The stacked portion 11d is separated in the direction of an X-Y plane to form a plurality of interconnect portions 12 on the peripheral circuit region Rc as illustrated in FIG. 10. RIE, for example, is used as a method for separating the stacked portion 11d.

Each interconnect portion 12, for example, is in contact with the contact portion CN that is connected to the gate electrode 65 and each of the diffusion layers 64a and 64b of the transistor 60. Accordingly, the interconnect portion 12 is electrically connected to the gate electrode 65 and each of the diffusion layers 64a and 64b through the contact portion CN.

Thereafter, the insulating layer 46 formed on the wall surface of the stacked body 11 is removed. Then, the insulating layer 42 is formed around the interconnect portion 12. The space between the interconnect portions 12 is filled with the insulating layer 42.

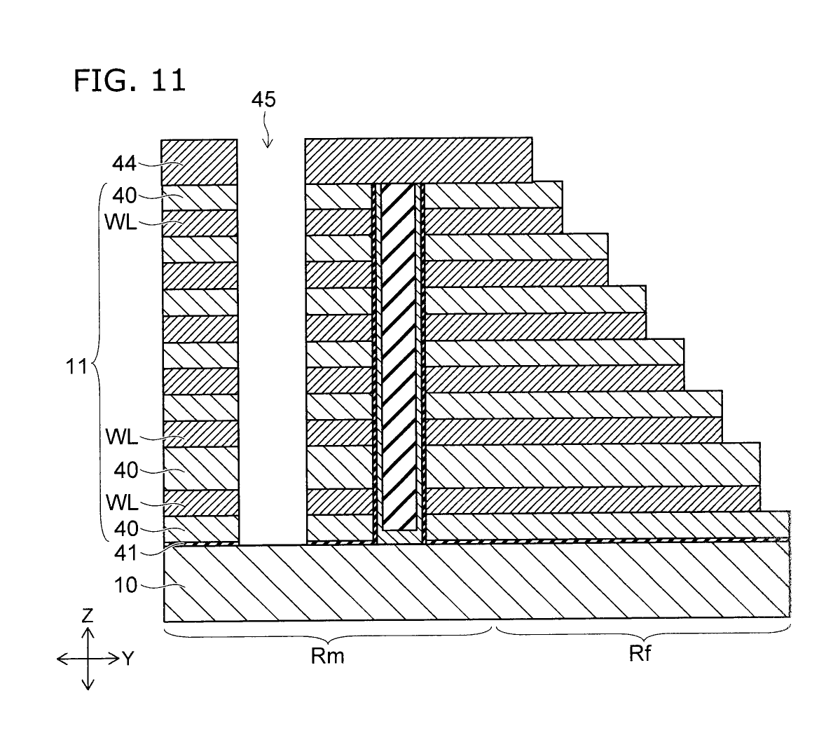

A flight portion is formed in the stacked body 11 on the flight region Rf by exposing the upper surface of the metal layer 40 as illustrated in FIG. 11. A flight portion may be formed in the stacked body 11 by, for example, exposing the upper surface of the electrode layer WL.

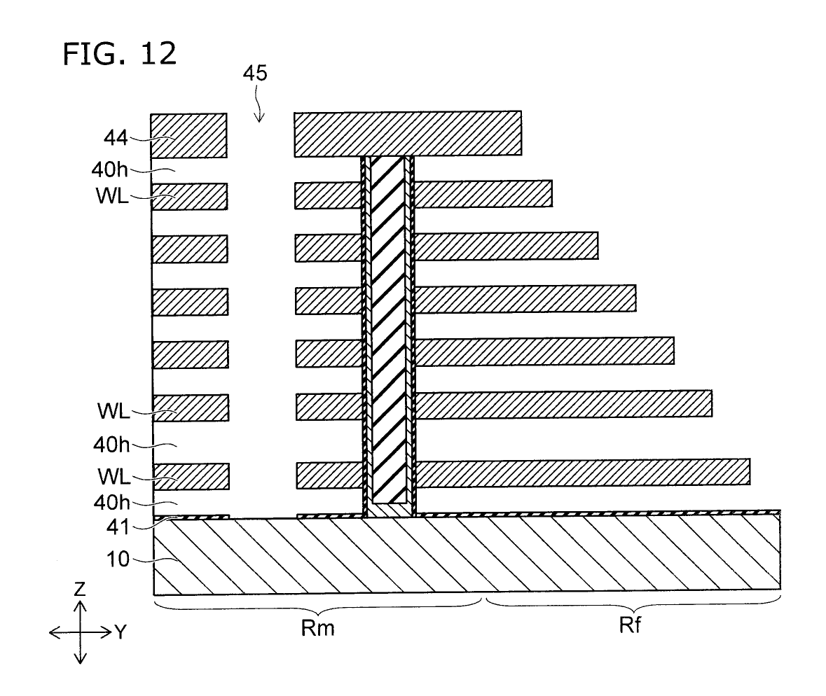

The metal layer 40 of the stacked body 11 is removed by etching through the groove 45 as illustrated in FIG. 12. Chemicals having a high selectivity of the electrode layer WL to the material of the metal layer 40 are used as an etching chemical.

Accordingly, a hollow 40h is formed where the metal layer 40 is removed. The stacked body 11 is supported by the columnar portion CL. At this time, the interconnect portion 12 on the peripheral circuit region Rc is covered by the insulating layer 42. For this reason, the metal layer 40 that is formed in the interconnect portion 12 is not removed.

Next, the insulating film 45a is formed on the side wall of the groove 45. The source layer SL, for example, is formed inside the insulating film 45a. Thereafter, the insulating layer 42 is formed on the stacked body 11 on the flight region Rf. Accordingly, the hollow 40h that is formed between each electrode layer WL is covered by the insulating film 45a and the insulating layer 42 to form the void 40s. The insulating layer 42 completely covers the side surface of the stacked body 11 and the surrounds of the interconnect portion 12.

Thereafter, the conductive film 44, for example, is processed as a part of the contact of the columnar portion CL. The insulating layer 42 is also formed on the stacked body 11. An insulating layer 43 is formed on the insulating layer 42 that mostly covers from the stacked body 11 to the interconnect portion 12.

The contact portion Cf is formed over the flight region Rf penetrating the insulating layers 42 and 43 to reach the upper surface of the electrode layer WL of the stacked body 11 as illustrated in FIG. 2 and FIG. 3. A contact portion Cc is formed over the peripheral circuit region Rc penetrating the insulating layer 43 to reach the interconnect portion 12.

The contact portion Cm is formed over the memory region Rm penetrating the insulating layer 43 to reach the source layer SL and the columnar portion CL as illustrated in FIG. 2.

Thereafter, unillustrated wiring and the like are formed on each of the contact portions Cc, Cf, and Cm, and the semiconductor memory device of the embodiment is formed.

According to the embodiment, metal (for example, tungsten) is used in the electrode layer WL in the memory region Rm. Accordingly, the resistance of the electrode layer WL can be lowered. For this reason, delays in writing, deleting, and reading operations of the memory can be suppressed.

Furthermore, the void 40s is formed between the electrode layers WL of the stacked body 11 in the memory region Rm. Accordingly, capacitance can be lowered between the electrode layers WL.

In addition to the above description, the metal layer 40 that is removed when forming the void 40s of the stacked body 11 is not removed but remains being formed in the interconnect portion 12 in the peripheral circuit region Rc. Accordingly, the interconnect portion 12 in the peripheral circuit region Rc can be used as low-resistance wiring (contact) that electrically connects the transistor 60 to the outside. For this reason, the speed of operation of the memory can be increased.

A silicon film forming device and an insulating film forming device are alternately used when, for example, the stacked body is structured in a manner in which polysilicon and an insulating film are alternately stacked on each other. For this reason, it takes time to form the stacked body. In addition, it is necessary for the type of a process gas to be changed depending on the material stacked in the stacked body when a dry process (for example, RIE) is used. Moreover, a choice of the material of a hard mask is narrow.

Regarding this, two types of metal are used in the stacked body 11 according to the embodiment. Accordingly, a time of forming the stacked body 11 can be shortened. In addition, it is not necessary for the type of the process gas to be changed when a dry process is used. Moreover, a choice of the material of a hard mask is wide. Furthermore, the interconnect portion 12 that is separated from the stacked body 11 can be used as a dummy pattern in a CMP process. For this reason, the manufacturing process can be realized with high efficiency.

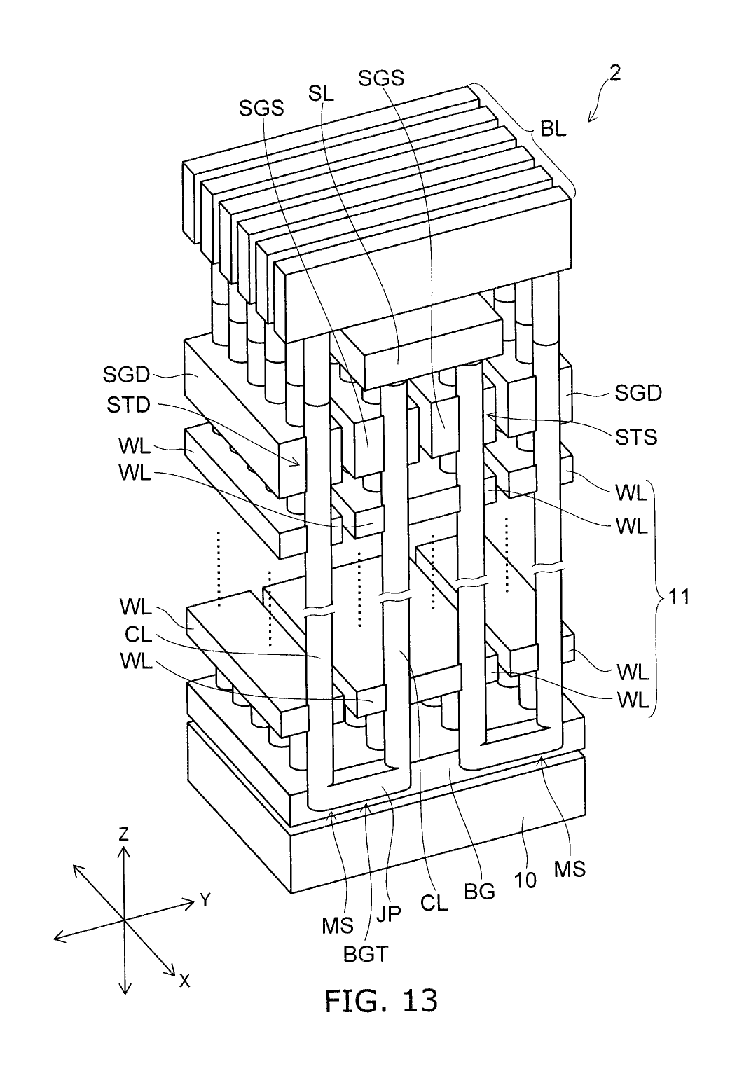

FIG. 13 is a schematic view of another example of the memory cell array in the semiconductor memory device of the embodiment. FIG. 13 illustrates a schematic perspective view of a memory cell array 2, and FIG. 11 illustrates a schematic plan view of the memory cell array 2.

In FIG. 13, illustrations of an insulating layer and the like are omitted for easy understanding as in FIG. 1. The uppermost electrode layer WL of the stacked body 11 is illustrated in FIG. 13.

A back gate BG is disposed on the substrate 10 with an insulating layer interposed therebetween. The stacked body 11 in which the plurality of electrode layers WL is stacked with the hollow 40h interposed therebetween is disposed on the back gate BG.

One memory string MS is formed as a U shape and includes a pair of columnar portions CL that extends in the Z-direction and a junction portion JP that joins each of the lower ends of the pair of columnar portions CL. The columnar portion CL, for example, is formed as a cylinder or an elliptic cylinder and penetrates the stacked body 11 to reach the back gate BG.

The drain-side selector gate SGD is disposed in one upper end portion of the pair of columnar portions CL, and the source-side selector gate SGS is disposed in the other upper end portion in the U-shaped memory string MS. The drain-side selector gate SGD and the source-side selector gate SGS are disposed on the uppermost electrode layer WL with an insulating layer interposed therebetween. The stacked body 11 includes the source-side selector gate SGS, the drain-side selector gate SGD, and the plurality of electrode layers WL.

The drain-side selector gate SGD and the source-side selector gate SGS are separated by the groove 45 in the Y-direction. The stacked body 11 that includes the drain-side selector gate SGD and the stacked body 11 that includes the source-side selector gate SGS are separated by the groove 45 in the Y-direction. That is, the stacked body 11 of the memory string MS between the pair of columnar portions CL is separated by the groove 45 in the Y-direction.

The source layer SL is disposed on the source-side selector gate SGS with an insulating layer interposed therebetween. A plurality of bit lines BL is disposed on the drain-side selector gate SGD and on the source layer SL with an insulating layer interposed therebetween. Each bit line BL extends in the Y-direction.

The interconnect portion 12 is disposed on the peripheral circuit region Rc also in the case of using the memory cell array 2. Accordingly, the interconnect portion 12 can be used as wiring (contact) with low electrical resistance as in the case of the above-described embodiment. This can increase the speed of operation of the memory. In addition, wiring does not have to be newly formed. Thus, the manufacturing process can be shortened.

In addition to the above description, the void 40s is disposed between the electrode layers WL of the stacked body 11. Accordingly, capacitance can be lowered between the electrode layers WL. Furthermore, using metal in the electrode layer WL can reduce the resistance.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a substrate;
a stacked body provided on the substrate and including a plurality of electrode layers separately stacked each other;
a transistor provided on the substrate; and
the interconnect portion electrically connected to the transistor and including a plurality of first metal layers separately stacked each other and a plurality of second metal layers provided between the plurality of first metal layers, the plurality of first metal layer having a same material as the plurality of electrode layer.

2. The device according to claim 1, wherein
a number of the plurality of electrode layers is smaller than or equal to a number of the plurality of first metal layers.

3. The device according to claim 1, wherein
a thickness of the plurality of electrode layers equals a thickness of the plurality of first metal layers.

4. The device according to claim 1, wherein
a resistance value of the plurality of first metal layers is smaller than a resistance value of the plurality of second metal layers.

5. The device according to claim 1, wherein
the plurality of electrode layers and the plurality of first metal layers include tungsten.

6. The device according to claim 1, wherein
the plurality of second metal layers includes at least one of titanium and molybdenum.

7. The device according to claim 1, wherein
the plurality of electrode layers is provided in a staircase pattern.

8. The device according to claim 1, further comprising:
a contact portion provided between the transistor and the interconnect portion,
wherein the transistor is electrically connected to the interconnect portion through the contact portion.

9. The device according to claim 1, further comprising:
a semiconductor body provided in the stacked body and extending in stacking direction of the stacked body; and
the charge storage film provided between the semiconductor body and the plurality of electrode layers.

10. A method for manufacturing a semiconductor memory device comprising:
forming a transistor on a predefined region of a substrate;
forming a stacked body including a plurality of first metal layers and a plurality of second metal layers, the plurality of first metal layers separately stacked each other above the transistor and the substrate, the plurality of second metal layer provided between the plurality of first metal layer;
forming a groove penetrating the stacked body in a direction of stacking in the stacked body to reach the substrate;
separating the stacked body into a first stacked portion and a second stacked portion, the first stacked portion including the plurality of first metal layers and the plurality of second metal layers stacked on the transistor, the second stacked portion including the groove, the plurality of first metal layers and the plurality of second metal layers stacked above the substrate;
separating the first stacked portion into a plurality of interconnect portions electrically connected to the transistor; and
removing the plurality of second metal layers of the second stacked portion by etching through the groove of the second stacked portion.

11. The method according to claim 10, wherein
a number of the plurality of first metal layers of the second stacked portion is smaller than or equal to a number of the plurality of first metal layers of the interconnect portion.

12. The method according to claim 10, wherein
a thickness of the plurality of first metal layers of the second stacked portion equals a thickness of the plurality of first metal layers of the interconnect portion.

13. The method according to claim 10, wherein
a resistance value of the plurality of first metal layers is smaller than a resistance value of the plurality of second metal layers.

14. The method according to claim 10, wherein
the plurality of first metal layers includes tungsten.

15. The method according to claim 10, wherein
the plurality of second metal layers includes at least one of titanium and molybdenum.

16. The method according to claim 10, further comprising:
forming a flight portion by exposing an upper surface of the plurality of first metal layers of the second stacked portion.

17. The method according to claim 16, further comprising:
forming a contact portion electrically connecting the plurality of first metal layers of the second stacked portion and the interconnect portion in the flight portion of the second stacked portion.

18. The method according to claim 10, further comprising:
forming a hole penetrating the second stacked portion in the direction of stacking to reach the substrate;
forming a film including a charge storage film on an inner wall of the hole;
forming a semiconductor body inside the film including the charge storage film.
